(19) United States
(12) Patent Application Publication
(10) Pub. No.: US 2026/0296955 A1
(43) Pub. Date: Oct. 1, 2026

(54) METHOD FOR MANUFACTURING ANTI-GLARE GLASS

(71) Applicant: Wuhu Token Sciences Co., Ltd., Wuhu (CN)

(72) Inventors: Jianjun ZHENG, Wuhu (CN); Suwen ZHONG, Wuhu (CN); Zhihui YU, Wuhu (CN); Xiaofei LI, Wuhu (CN); Song XU, Wuhu (CN); Yu GU, Wuhu (CN)

(73) Assignee: Wuhu Token Sciences Co.,Ltd., Wuhu (CN)

(21) Appl. No.: 19/551,640

(22) Filed: Feb. 27, 2026

(30) Foreign Application Priority Data
Mar. 28, 2025 (CN) 2025103822650

(51) Int. Cl. C03C 15/00; H05K 5/03

(52) U.S. Cl. CPC C03C 15/00; H05K 5/03

(57) ABSTRACT

Disclosed is a method for manufacturing anti-glare glass, including the following steps: performing surface cleaning on a glass substrate; depositing a film layer on a surface of the glass substrate; coating the film layer with photoresist; carrying out exposure, development and film layer etching; performing dry etching to directionally etch a longitudinal depth of the glass, followed by wet etching to simultaneously etch in both longitudinal and transverse directions to obtain a specific aspect ratio and increase an anti-glare area; or performing wet etching to construct a preliminary morphology on the glass surface, followed by dry etching to achieve precise depth control and feature shaping in specific areas. The method can effectively improve anti-glare performance and approach the disordered diffusion effect of frosted glass; and the surface texture distribution is more uniform, overcoming the defects of the conventional frosting process.

### CROSS-REFERENCE TO RELATED APPLICATIONS

The application claims priority to Chinese patent application No. 2025103822650, filed on Mar. 28, 2025, the entire contents of which are incorporated herein by reference.

### TECHNICAL FIELD

The present disclosure relates to the technical field of anti-glare glass, and in particular, to a method for manufacturing anti-glare glass.

### BACKGROUND

With the rapid development of display technology, anti-glare (AG) glass, as a key optical component for improving display performance, has undergone continuous innovation and evolution in its manufacturing processes. At present, the main manufacturing methods of AG glass include a chemical frosting process, a photolithography-based etching process, and an AG spray coating process, each of which has demonstrated respective advantages and limitations in practical applications.

The conventional chemical frosting process adopts chemical reagents such as glass frosting powder to perform wet etching on a glass surface, forming randomly distributed micron-scale rough structures. Although this process features low cost and simple operation, the randomness of chemical reactions makes it difficult to precisely control the size and distribution of surface microstructures, which in turn affects the optical performance and batch consistency of products. Moreover, the rough surface formed by the frosting process tends to accumulate dirt, presenting certain defects.

The photolithography-based etching process draws on photolithography technology in semiconductor manufacturing. This involves coating the glass surface with photoresist, performing selective exposure and development with a photomask (MASK), and finally transferring microstructure pattern onto a glass substrate by wet etching. This method enables precise control over the size, shape and arrangement of microstructures. However, due to the isotropic nature of the conventional wet etching process, there are significant limitations in forming microstructures with high aspect ratios, which directly affects the anti-glare performance and sparkle point control of AG glass.

The AG spray coating process forms a functional layer with a light-scattering effect by spraying a coating containing specific components onto the glass surface. This method features simple procedures and high efficiency, but the adhesion and durability of the coating typically do not meet the requirements of high-end display products, and the coating tends to age or delaminate under certain application conditions, resulting in limited service life.

With display technology evolving towards high resolution and large size, the market demand for the performance of AG glass is constantly increasing. Especially in fields such as medical display and professional image processing, higher requirements are imposed on anti-glare effect and sparkle point control. However, the existing pure wet etching process has encountered bottlenecks in improving microstructure performance, making it difficult to simultaneously achieve excellent anti-glare performance and low sparkle point characteristics.

With the rapid development of display technology, AG glass has become increasingly critical for improving display performance. However, the existing AG glass manufacturing technologies still have obvious shortcomings in optical performance and display effect, making it difficult to meet the ever-increasing performance requirements of the high-end display field. At present, the mainstream manufacturing methods such as chemical frosting, photolithography-based etching, and spray coating face fundamental technical bottlenecks. The existing technologies have the following defects:
1. The chemical frosting process uses glass frosting powder with a disordered particle size distribution to etch the glass surface. This process, characterized by random distribution, exhibits excellent anti-glare performance. However, since the particle sizes of the glass frosting powder vary and are difficult to precisely control, the etching process inevitably brings about problems such as uneven sparkle points and inconsistent surface texture roughness. Especially in scenarios that emphasize visual experience under high ambient brightness, this uneven distribution may cause phenomena such as localized bright spots or glare, affecting the consistency and aesthetics of the overall product. In addition, glass frosting powder from different batches or suppliers may vary in particle morphology and chemical properties, further amplifying process variability. During the manufacturing process, fluctuations in process parameters (such as temperature, concentration, and time) may lead to significant differences in product quality, hindering the achievement of mass production.
2. The photolithography-based etching process, which draws on photolithography technology from the semiconductor industry, achieves precise control of microstructures through MASK pattern. This method can form microstructures with uniform size and controllable distribution, facilitating superior performance in sparkle point control. However, due to the regularity of the MASK pattern, the formed microstructures are relatively ordered in arrangement and lack sufficient randomness, resulting in inferior anti-glare performance compared with the frosting process. Especially when viewed at wide angles, the regularly arranged microstructures may cause optical interference phenomena, affecting display quality. Moreover, due to the isotropic nature of the conventional wet etching process, it is difficult to form an ideal aspect ratio, which further limits the improvement of anti-glare performance.
3. The spray coating method forms a functional layer by spraying materials containing specific particles onto the glass surface. Although this additive manufacturing process is simple to operate, it has serious reliability problems. The most prominent defect is that the wear resistance of its products is far lower than that of products of subtractive manufacturing processes (such as the chemical frosting and the photolithography-based etching). This is because the adhesion of the sprayed functional coating to the substrate is inherently weaker than that of microstructures formed by chemical or physical etching. In practical applications, the sprayed coating is susceptible to damage or delamination due to mechanical actions such as abrasion and impact, leading to a significant reduction in product service life. In addition, the uniformity and repeatability of the spray coating process are difficult to guarantee, which affects the stability of product quality.

A method for manufacturing AG glass as disclosed in patent CN119143400A includes the following steps: performing surface treatment on a glass substrate; uniformly coating a surface of the glass substrate with functional coating; uniformly coating a surface of the functional coating with photoresist, and performing a soft bake after the coating; using a high-precision MASK for pattern design and exposure, and precisely transferring designed microstructure pattern to the photoresist layer; performing development after exposure to remove the unexposed photoresist portion and form predetermined pattern on the glass substrate; curing the developed photoresist pattern to ensure that the pattern has sufficient etch resistance and stability in the subsequent etching process; performing etching to remove the unprotected functional coating and glass substrate for formation of precise microstructure pattern; removing the residual photoresist with photoresist removal technology to obtain final microstructure pattern; and functionalizing the surface of the microstructure pattern through fluorination treatment. The anti-glare effect needs to be improved.

### SUMMARY

In view of the shortcomings in the prior art, the present disclosure provides a method for manufacturing anti-glare glass to obtain better anti-glare effect and achieve sparkle point control.

To solve the above technical problems, the technical solution adopted by the present disclosure is as follows:

A method for manufacturing anti-glare glass includes the following steps:
step 1: performing surface cleaning on a glass substrate;
step 2: depositing a film layer on a surface of the glass substrate;
step 3: coating the film layer with photoresist;
step 4: carrying out exposure, development and film layer etching; and
step 5: performing dry etching to directionally etch a longitudinal depth of the glass, followed by wet etching to simultaneously etch in both longitudinal and transverse directions to obtain a specific aspect ratio and increase an anti-glare area; or performing wet etching to construct a preliminary morphology on the glass surface, followed by dry etching to achieve precise depth control and feature shaping in specific areas.

Further or preferably,
a process flow in step 5 is as follows:
dry etching of glass→photoresist stripping→wet etching of glass 1→film layer removal→wet etching of glass 2;
or dry etching of glass→wet etching of glass 1→photoresist stripping→film layer removal→wet etching of glass 2;
or photoresist stripping→dry etching of glass→wet etching of glass 1→film layer removal→wet etching of glass 2;
or photoresist stripping→wet etching of glass 1→dry etching of glass→film layer removal→wet etching of glass 2;
or wet etching of glass 1→photoresist stripping→dry etching of glass→film layer removal→wet etching of glass 2;
or wet etching of glass 1→dry etching of glass→photoresist stripping→film layer removal→wet etching of glass 2.

In step 1, preliminary rinsing is performed on the surface of the glass substrate with deionized water in combination with a soft brush or ultrasonic means to remove dust and organic impurities therefrom; or a cleaning agent or solvent is added for degreasing and oil removal at 20-100 °C for 1-10 min.

In step 2, a thickness of the film layer ranges from 50 Å to 3000 Å, and the film layer is formed by vacuum deposition or evaporation deposition.

In step 3, a thickness of the photoresist ranges from 0.5 μm to 20 μm; the coating is performed by a slot die coating method, with a coating speed controlled within a range of 10-200 mm/s, and a spray pressure maintained at 0.03-0.98 MPa; and after the coating, a soft bake is carried out at 50-200 °C for 30-300 s.

In step 4, for the exposure process, a contact aligner, a proximity aligner, or a projection aligner is selected according to batch and resolution requirements, with exposure energy ranging from 50 mJ/cm² to 500 mJ/cm².

In step 4, the development lasts for about 30-90 s and is maintained at a constant temperature within a range of 20-30 °C, and a conductivity of a developing solution is kept within a range of 1-80 mS/cm; and after the development, a post-development bake is carried out at 50-300 °C for 1-20 min.

In step 4, prior to the film layer etching, a photoresist pattern is cured by thermal curing or ultraviolet (UV) curing at 50-500 °C for 1-60 min to enhance the etch resistance and mechanical strength of the photoresist pattern and prevent deformation or delamination during the etching process.

In step 5, the dry etching process is as follows:
in the dry etching step, an inductively coupled plasma technology is used for precise microstructure processing of anti-glare glass; and the dry etching is used for performing directional etching on the glass by a plasma etching technology;
in terms of process parameter setting, a vacuum system is maintained at 0.1-10 Torr to ensure the stability of plasma and sufficient dissociation of gases; and in terms of gas flow rates, flow rates of main etching gases (C4F₆ and SF₆) are controlled within a range of 50-200 sccm, a flow rate of an inert gas (Ar or He) is set at 50 -150 sccm, and a flow rate of O₂, if required, is controlled at 5-20 sccm.

In step 5, during the wet etching stage, isotropic etching is performed on the microstructures using chemical reagents to achieve a transition from simple longitudinal recesses to complex three-dimensional structures; and wet etching enables the simultaneous etching of width and depth in both the transverse and longitudinal directions.

Compared with the prior art, the present disclosure has the following advantages:

According to the present disclosure, the method for manufacturing AG glass combining dry and wet etching has achieved significant breakthroughs in anti-glare performance, sparkle point control, and wear resistance by innovatively combining dry etching and wet etching processes, providing a brand-new technical solution for the high-end display field. Specifically in the following aspects:

In terms of anti-glare performance, the present disclosure fully leverages the process advantages of a combination of dry etching and wet etching processes. First, a base structure with a relatively high aspect ratio is formed by dry etching, and then precision tuning is performed by wet etching at an optimized ratio, ultimately achieving an anti-glare effect equivalent to that of the conventional frosting process. This composite process not only provides a larger scattering area, but also ensures the stability and repeatability of product performance through precise parameter control, thereby solving the problem of uncontrollable microstructures in the conventional frosting process.

In terms of sparkle point control, the present disclosure adopts the same photolithography technology as the photolithography-based etching process as a pattern transfer means. Through the precise design and transfer of MASK pattern, the uniform distribution of microstructures is achieved. Combined with the synergistic effect of dry and wet etching, the sparkle point phenomenon is effectively suppressed while maintaining excellent anti-glare performance. This precisely controllable manufacturing method enables the product to still maintain an excellent display effect in high-brightness display environments, thereby significantly improving the user experience.

In terms of wear resistance, the present disclosure is completely based on a subtractive manufacturing process, which overcomes the inherent defect of insufficient bonding force of the coating in the spray coating method. In particular, the high-aspect-ratio structure formed by dry etching provides an ideal foundation for subsequent wet etching, so that the finally formed microstructures are firmly bonded to the glass substrate. Experiments show that the AG glass manufactured according to the present disclosure performs the best in wear resistance tests, which is far superior to that manufactured by the conventional spray coating process, and also surpasses the products manufactured by the frosting process or photolithography-based etching process alone.

In addition, the present disclosure also has obvious advantages in process controllability. By precisely controlling the process parameters of dry and wet etching, the aspect ratio, morphological characteristics and distribution density of microstructures can be flexibly tuned, so as to meet the optical performance requirements of different application scenarios. Furthermore, the process exhibits excellent repeatability and high stability, which is conducive to the mass production of products.

### BRIEF DESCRIPTION OF DRAWINGS

The following provides a brief description of the contents expressed in the accompanying drawings of this Description and the reference numerals therein:

FIG. 1 is a schematic diagram of a manufacturing process flow 1 of the present disclosure.

FIG. 2 is a schematic diagram of a manufacturing process flow 2 of the present disclosure.

FIG. 3 is a schematic diagram of a manufacturing process flow 3 of the present disclosure.

FIG. 4 is a schematic diagram of a manufacturing process flow 4 of the present disclosure.

FIG. 5 is a schematic diagram of a manufacturing process flow 5 of the present disclosure.

FIG. 6 is a schematic diagram of a manufacturing process flow 6 of the present disclosure.

FIG. 7 is a schematic diagram of a manufacturing process flow of photolithography-based AG glass according to the present disclosure.

FIG. 8 is a schematic diagram of the present disclosure before dry etching.

FIG. 9 is a schematic diagram of the present disclosure after dry etching.

FIG. 10 is a schematic diagram of the present disclosure after dry etching and wet etching.

FIG. 11 is a schematic diagram of FIG. 10 with photoresist being stripped.

FIG. 12 is a schematic diagram of the present disclosure with a removed barrier layer.

FIG. 13 is a schematic diagram showing the comparison between a hybrid dry-wet etched structure and the single wet etched structure of the present disclosure.

### DETAILED DESCRIPTION OF THE EMBODIMENTS

The specific implementations of the present disclosure will be further explained in detail below through the description of embodiments with reference to the accompanying drawings.

A method for manufacturing anti-glare glass includes the following steps:
step 1: performing surface cleaning on a glass substrate;
step 2: depositing a film layer on a surface of the glass substrate;
step 3: coating the film layer with photoresist;
step 4: carrying out exposure, development and film layer etching; and
step 5: performing dry etching to directionally etch a longitudinal depth of the glass, followed by wet etching to simultaneously etch in both longitudinal and transverse directions to obtain a specific aspect ratio and increase an anti-glare area; or performing wet etching to construct a preliminary morphology on the glass surface, followed by dry etching to achieve precise depth control and feature shaping in specific areas.

The present disclosure has made key improvements on the basis of the conventional photolithography-based etching. In the first process route, dry etching is first used for directional longitudinal etching of the glass, thereby preforming structural features with a certain depth on the glass surface. Subsequent wet etching continues simultaneously in both longitudinal and transverse directions, expanding the existing vertical grooves transversely and deepening them further, so as to obtain a relatively high aspect ratio. Through this “dry first, then wet” composite etching process, both the transverse and longitudinal dimensions are taken into account.

The present disclosure also innovatively proposes the second process route, namely, wet etching is first adopted to carry out preliminary morphology construction on the glass surface, forming base microstructures with a certain opening width; and then, dry etching technology is employed to perform precise longitudinal etching on bottoms of the microstructures, forming a multi-layered pit-in-pit structure. This “wet first, then dry” process sequence can further increase the depth through the high directionality of dry etching while maintaining the lateral expansion advantage of wet etching, thereby achieving precision tuning of bottom regions of the microstructures.

The following effects are finally achieved: \textcircled{1} in terms of depth, the grooves and structures are more distinct, and the overall surface area is increased, which can effectively improve the anti-glare performance and approach the disordered diffusion effect achieved by the frosting process; \textcircled{2} the surface texture ensures a more uniform distribution of the microstructures under the synergistic effect of mask exposure, overcoming the defects of uneven sparkle points and difficulty in precise control of surface microstructures in the conventional frosting process; and \textcircled{3} compared with the spray coating process which only covers a functional layer on the glass surface, the present disclosure adopts an etching process to directly form microstructures on the glass substrate, and such surface texture originating from the material itself have a natural wear resistance advantage, which can meet the reliability requirements under various harsh service conditions.

Preferred embodiments of the present disclosure are:

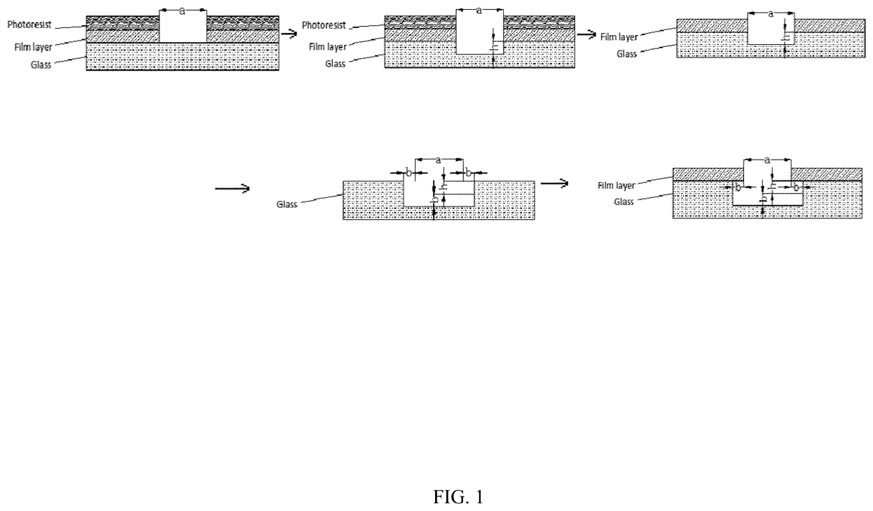

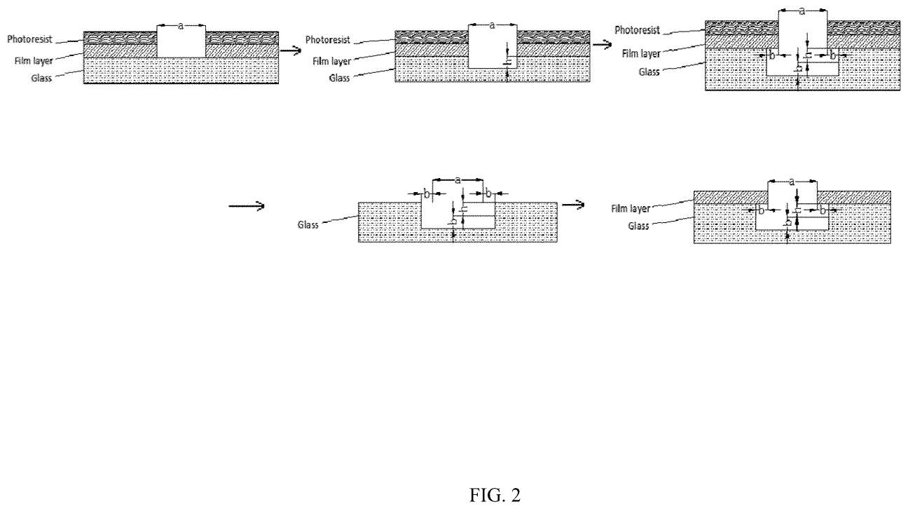

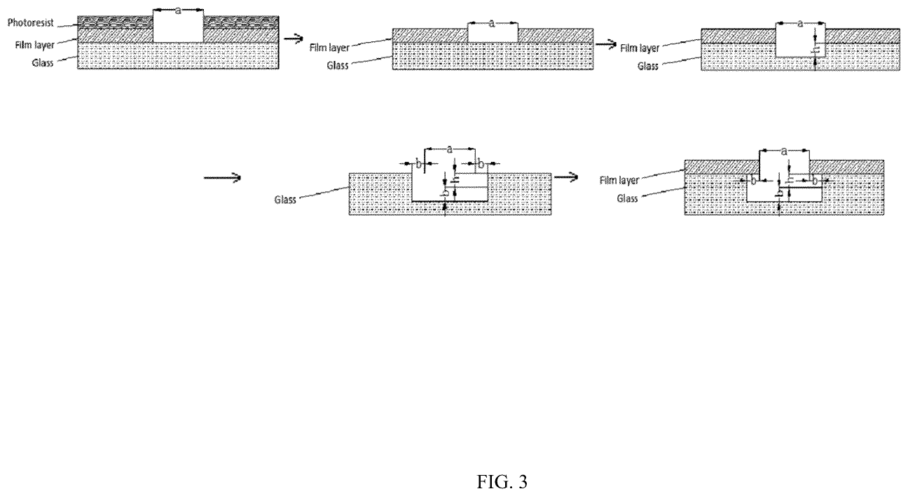

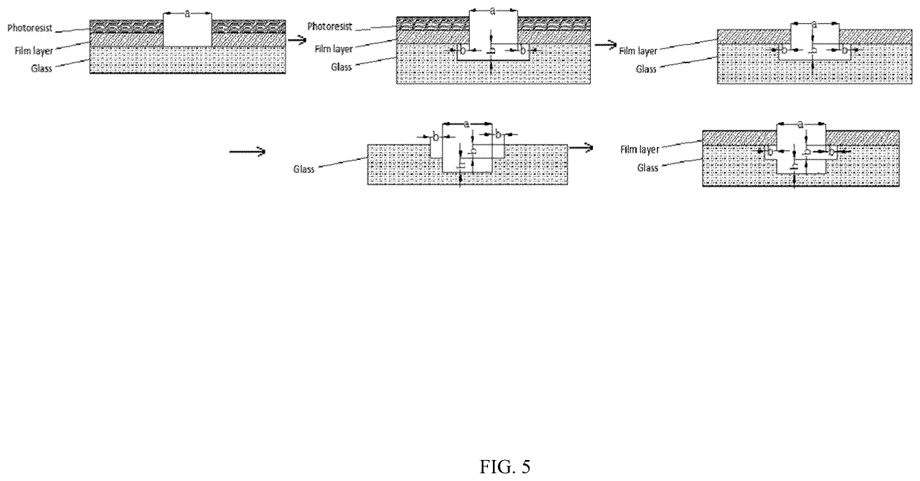

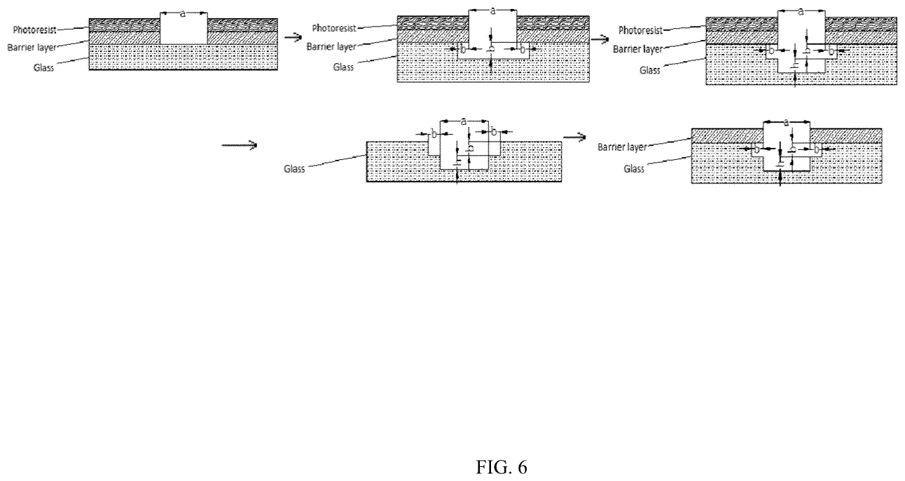

The present disclosure proposes an innovative hybrid dry-wet etching process. This method combines the directional advantage of dry etching and the uniformity characteristic of wet etching, and achieves precision tuning of microstructure morphology through the synergistic effect of multi-step operations. Specifically, on the basis of the conventional photolithography-based etching process, a breakthrough in process performance is achieved by introducing a dry etching step. According to the coordination method of the film layer and the photoresist as well as the sequence of dry and wet etching, there are six main process routes (as shown in FIG. 1 to FIG. 6: Processes 1 to 6):
Process 1: Glass substrate→film layer depositing→photoresist coating→exposure→development→film layer etching→dry etching of glass→photoresist stripping→wet etching of glass 1→film layer removal→wet etching of glass 2
Process 2: Glass substrate→film layer depositing→photoresist coating→exposure→development→film layer etching→dry etching of glass→wet etching of glass 1→photoresist stripping→film layer removal→wet etching of glass 2
Process 3: Glass substrate→film layer depositing→photoresist coating→exposure→development→film layer etching→photoresist stripping→dry etching of glass→wet etching of glass 1→film layer removal→wet etching of glass 2
Process 4: Glass substrate→film layer depositing→photoresist coating→exposure→development→film layer etching→photoresist stripping→wet etching of glass 1→dry etching of glass→film layer removal→wet etching of glass 2
Process 5: Glass substrate→film layer depositing→photoresist coating→exposure→development→film layer etching→wet etching of glass 1→photoresist stripping→dry etching of glass→film layer removal→wet etching of glass 2
Process 6: Glass substrate→film layer depositing→photoresist coating→exposure→development→film layer etching→wet etching of glass 1→dry etching of glass→photoresist stripping→film layer removal→wet etching of glass 2

The common feature of Process 1 and Process 2 is that both the film layer and photoresist are retained simultaneously during the dry etching stage, forming a dual-protection structure. Specifically, a film layer is first deposited on the glass substrate, followed by coating and patterning of photoresist on the film layer; and then, dry etching is employed to precisely transfer microstructures. This route fully leverages the advantages of the dual protection provided by the photoresist and the film layer, ensuring high fidelity and morphological stability of the microstructures after dry etching. The difference between the two processes lies in the timing of photoresist removal: in Process 1, the photoresist is removed immediately after dry etching, while in Process 2, the photoresist is not removed until both dry etching and the first wet etching are completed.

The notable feature of Process 3 is that the photoresist is removed before dry etching, and only the film layer is used as an etching MASK. This process route simplifies the manufacturing process and reduces the adverse effects that may occur to the photoresist in the dry etching environment, such as thermal deformation or degradation. By only using the film layer to protect the selected area, the desired morphological requirements can also be achieved in dry etching.

For Processes 4, 5, and 6, dry etching is performed after wet etching. These routes first rely on wet etching to carry out preliminary morphology construction on the glass surface, and then employ dry etching technology to achieve precise depth control and feature shaping in specific areas. This “reverse” processing method provides new possibilities for the tuning of microstructure morphology. The initial contour is first formed by wet etching, and then the directional characteristics of dry etching are used for precision tuning, which can obtain special surface morphologies that are difficult to achieve with conventional processes.

The step of photoresist stripping has a certain flexibility in the above-mentioned processes, and the timing for removing the photoresist layer can be selected according to actual requirements to meet the optical and mechanical performance requirements of each stage, all of which fall within the protection scope of this patent.

The present disclosure preferably adopts the “dry first, then wet” composite etching process. On the basis of photolithography-based etching, this method first uses dry etching with strong directionality to improve the aspect ratio of microstructures, and then uses wet etching to optimize the surface morphology, which achieves precision tuning of the geometric characteristics of microstructures, thereby obtaining high-performance AG glass.

According to the present disclosure, the method for manufacturing AG glass combining dry and wet etching has achieved significant breakthroughs in anti-glare performance, sparkle point control, and wear resistance by innovatively combining dry etching and wet etching processes, providing a brand-new technical solution for the high-end display field. Specifically in the following aspects:
1. In terms of anti-glare performance, the present disclosure fully leverages the process advantages of a combination of dry etching and wet etching processes. First, a base structure with a relatively high aspect ratio is formed by dry etching, and then precision tuning is performed by wet etching at an optimized ratio, ultimately achieving an anti-glare effect equivalent to that of the conventional frosting process. This composite process not only provides a larger scattering area, but also ensures the stability and repeatability of product performance through precise parameter control, thereby solving the problem of uncontrollable microstructures in the conventional frosting process.
2. In terms of sparkle point control, the present disclosure adopts the same photolithography technology as the photolithography-based etching process as a pattern transfer means. Through the precise design and transfer of MASK pattern, the uniform distribution of microstructures is achieved. Combined with the synergistic effect of dry and wet etching, the sparkle point phenomenon is effectively suppressed while maintaining excellent anti-glare performance. This precisely controllable manufacturing method enables the product to still maintain an excellent display effect in high-brightness display environments, thereby significantly improving the user experience.
3. In terms of wear resistance, the present disclosure is completely based on a subtractive manufacturing process, which overcomes the inherent defect of insufficient bonding force of the coating in the spray coating method. In particular, the high-aspect-ratio structure formed by dry etching provides an ideal foundation for subsequent wet etching, so that the finally formed microstructures are firmly bonded to the glass substrate. Experiments show that the AG glass manufactured according to the present disclosure performs the best in wear resistance tests, which is far superior to that manufactured by the conventional spray coating process, and also surpasses the products manufactured by the frosting process or photolithography-based etching process alone.

In addition, the present disclosure also has obvious advantages in process controllability. By precisely controlling the process parameters of dry and wet etching, the aspect ratio, morphological characteristics and distribution density of microstructures can be flexibly tuned, so as to meet the optical performance requirements of different application scenarios. Furthermore, the process exhibits excellent repeatability and high stability, which is conducive to the mass production of products.

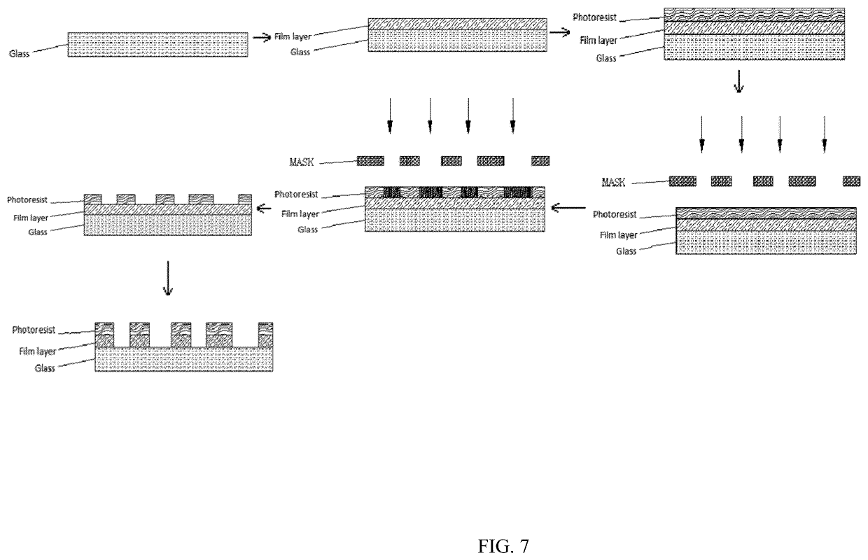

As shown in FIG. 7 to FIG. 13, the specific process of the hybrid dry-wet etching method is as follows (the process details and technical parameters of each step will be described below to facilitate the understanding of the implementation details of the entire manufacturing process and the impact on the final product performance):

### A. Glass Substrate Treatment

Preliminary rinsing is performed on the surface of a glass substrate with deionized water in combination with a soft brush or ultrasonic means to remove dust and organic impurities therefrom;

and if necessary, a low-concentration cleaning agent or solvent may be added for degreasing and oil removal. The treatment temperature ranges from 20 °C to 100 °C, and the treatment duration is 1-10 min.

### B. Film Layer Depositing

The film layer plays a vital role in the present disclosure. It serves not only as a MASK for subsequent dry etching, but also as a key element for precisely controlling the microstructure morphology in the wet etching process. The material options for the film layer may include various types such as ITO (indium tin oxide), Cr (chromium), Mo (molybdenum), SiO₂ (silicon dioxide) and Si₃N₄ (silicon nitride). These materials have distinct characteristics and can be flexibly selected according to actual process requirements and cost considerations, thereby ensuring that the film layer provides necessary protection and performance support during the etching process.

The thickness of the film layer is usually controlled within a range of 50-3000 Å (angstrom), and the specific value depends on the process conditions of the subsequent dry etching and the requirements for the aspect ratio of the microstructures. Although a thicker film layer can offer better protection, it also increases the etching difficulty and material cost; and a thinner film layer, on the other hand, may suffer damage during the etching process, which may affect the integrity of the microstructures.

The manufacturing methods of the film layer mainly adopt vacuum deposition or evaporation deposition technology, including but not limited to physical vapor deposition (PVD), chemical vapor deposition (CVD) and sputter deposition. These technologies enable the formation of a uniform and dense thin film on the surface of the glass substrate with good adhesion.

Specifically, the key parameters of each film layer are as follows: for the ITO film layer, argon (Ar) is usually used for deposition, with a gas flow rate of 320-400 sccm, a vacuum degree controlled at 0.5 Pa, a coating temperature range of 150-300 °C, a power of 6-8 kW, and a gas supply ratio of 1:0.3. For the Cr film layer, Ar is used, with a gas flow rate of 320-400 sccm, a vacuum degree maintained at 0.5 Pa, a temperature range of 200-300 °C, a power set at 5-15 kW, and a gas ratio of 1:0. The manufacturing of the Mo film layer needs to be carried out under the conditions of a vacuum degree of 0.65 Pa, an Ar flow rate of 350-600 sccm, and an O₂ flow rate of 10-40 sccm, with a temperature controlled at 150-200 °C, a power of 6-12 kW, and a gas ratio of 10-40 sccm. For the SiO₂ film layer, Ar is used, with a gas flow rate of 100-180 sccm, a vacuum degree of 0.5 Pa, a coating temperature range of 200-300 °C, and a power of 10-20 kW. Finally, during the manufacturing of Si₃N₄, N₂ with a flow rate of 200-320 sccm and Ar with a flow rate of 100-150 sccm need to be introduced, with a vacuum degree of 0.6 Pa, a temperature range of 200-300 °C, a power of 20-45 kW, and a gas ratio of 25-60 sccm.

Note: The ratio range is determined by the characteristics of the film layer.

### C. Photoresist Coating

The choice of photoresist may be based on actual process requirements, using positive or negative photoresist materials. Positive photoresist has increased solubility in an exposed area and is removed after the development; and on the contrary, negative photoresist is crosslinked and cured in the exposed area and retained after the development. The thickness of the photoresist is usually controlled within a range of 0.5-20 μm to ensure the resolution and accuracy of subsequent pattern transfer.

The coating is performed by a slot die coating method, which is suitable for the rapid coating of large-area glass. The coating speed is generally controlled within a range of 10-200 mm/s to ensure uniform coverage. During the coating process, the GAP (a gap between the photoresist layer and the substrate) is maintained within a range of 50-300 μm, and a spray pressure is maintained at 0.03-0.98 MPa. After the coating, a soft bake is generally required to remove the solvent in the photoresist and improve the adhesion and stability of the photoresist. The soft bake temperature is generally controlled at 50-200 °C for a duration of 30-300 s. After the coating, the thickness and uniformity of the photoresist may be inspected by a film thickness tester or optical microscope to ensure that the photoresist layer meets the requirements of the subsequent photolithography process.

### D. MASK Pattern Design and Exposure

In the hybrid dry-wet etching process of the present disclosure, the MASK pattern design and exposure step plays a vital role in the dimensional accuracy and distribution uniformity of the final microstructures. First, according to the optical requirements of target AG glass, various forms such as dot matrix, linear array, honeycomb or polygon may be selected for MASK pattern design, with an aperture generally limited to a range of 1-200 μm. Based on the arrangement of patterns with different sizes, diversified distribution modes including normal distribution, exponential distribution, bimodal distribution or random distribution may be achieved, thereby achieving specific scattering and optical effects for different application scenarios.

For the exposure process, a contact aligner, a proximity aligner, or a projection aligner is selected according to batch and resolution requirements. The exposure energy is generally within a range of 50-500 mJ/cm²; and the specific value is jointly determined by photoresist characteristics, light source wavelength and resolution level. Commonly used UV wavelengths mainly include i-line (365 nm), h-line (405 nm) and g-line (436 nm). The selection of an appropriate wavelength is determined based on the specific application requirements and the photosensitive compatibility of the photoresist. If multi-layer exposure is required, the alignment error is controlled within a range of ±0.5 μm to 1 μm through a double-sided alignment system to ensure the precise matching of multi-layer patterns.

### E. Development

During development, a developing solution (e.g., a tetramethylammonium hydroxide (TMAH) or potassium hydroxide (KOH) solution) with a specific concentration is used. The development time is generally about 30-90 s, and development is maintained at a constant temperature within a range of 20-30 °C to achieve a stable developing rate and reliable pattern fidelity. In addition, a conductivity of the developing solution is kept within a range of 1-80 mS/cm to ensure uniform progress of chemical reactions during the development process. After the development, a post-development bake also needs to be carried out at 50-300 °C for 1-20 min, so as to further enhance the etch resistance of the photoresist and stabilize the pattern.

In practical operation, development may be carried out either by immersion or spraying. The immersion method improves development uniformity through slow stirring and allows for easier control of the overall rate; and the spraying method, on the other hand, shortens the development cycle but imposes higher requirements on flow rate and nozzle precision. After the development, the pattern edges and line widths are usually inspected by optical systems, online monitoring or an offline critical dimension scanning electron microscope (CD-SEM) to ensure sufficient development without excessive etching. After repeated rinsing with deionized water and rapid drying, a post-development bake may be performed at 50-300 °C for 1-20 min as required so as to further enhance the etch resistance of the photoresist pattern. Through the above development process, the photoresist layer can precisely reproduce the MASK pattern.

### F. Film Layer Etching

Prior to film layer etching, a photoresist pattern usually needs to be cured. Specifically, thermal curing or ultraviolet (UV) curing may be carried out within a temperature range of 50-500 °C for a duration of 1-60 min, so as to enhance the etch resistance and mechanical strength of the photoresist pattern and prevent deformation or delamination during the etching process. Only after the pattern curing is completed can the etching of the film layer be initiated.

The material options for the film layer may include ITO, Cr, Mo, SiO₂ and Si₃N₄. Corresponding etching solutions are adopted for the treatment of different types of film layers: for ITO, Cr and Mo film layers, a mixed solution of nitric acid or hydrochloric acid is mainly used, with a concentration controlled within a range of 1-10%; for SiO₂ film layers, hydrofluoric acid is adopted, with a concentration generally set at 5-20%; while for Si₃N₄ film layers, phosphoric acid is used, with a concentration range of 10-30%. The specific etching time depends on the film layer thickness (generally 50-3000 Å) as well as the depth and sidewall precision of the desired pattern.

During the etching process, timely observation and measurement are required to ensure that film layer pattern is completely transferred while avoiding excessive etching that can damage the substrate. Rapid inspection may be performed using an optical microscope to evaluate the critical dimensions and pattern edges. Immediately after etching, multi-stage cleaning is carried out using deionized water or corresponding cleaning agents to remove etching residues, followed by air drying or low-temperature drying in a clean environment. Through the above steps, the film layer pattern consistent with the photoresist pattern can be obtained on the glass surface, providing precise regional protection and guidance for the subsequent dry etching or wet etching processes.

### G. Dry Etching Process

The dry etching process employs inductively coupled plasma (ICP) technology for precise microstructure processing of AG glass. Building on the conventional glass etching technologies, this process is particularly suitable for meeting the requirements of microstructures with high aspect ratios. The etching process is conducted in a dry etching machine (such as a reactive ion etcher (RIE) or an inductively coupled plasma (ICP) etcher), where the ICP etcher generates high-density plasma via inductive coupling, enabling high-selectivity etching of various materials including silicon, silicon dioxide and metals.

The core of dry etching lies in the use of plasma etching technology to perform directional etching on glass. Fluorine-based gases (such as CF₄, C₄F₈, and SF₆) combined with inert gases (Ar, He) are generally selected for use. The most common etching gas used is a mixture of C₄F₆+H₂+Ar or C₄F₆+CH₂F₂+Ar. In this setup, C₄F₆ serves as a supply source for CF_{X} radicals, ensuring a stable supply of CF_{X} radicals during the etching process; and the generated CF_{X} radicals are responsible for chemically reacting with SiO₂ on the glass surface. H₂ and CH₂F₂ act as F⁻ scavengers, binding with free F⁻ ions to form HF gas, which effectively controls the selectivity of the etching reaction and thereby achieves directional tuning of the longitudinal etching depth of the glass. Ar mainly functions as a physical bombardment medium, and ion bombardment promotes the reaction between CF_{X} radicals and SiO₂, so that the etching rate is improved.

In terms of process parameter setting, a vacuum system is maintained at 0.1-10 Torr to ensure the stability of plasma and sufficient dissociation of gases. In terms of gas flow rates, flow rates of main etching gases (C₄F₆ and SF₆) are controlled within a range of 50-200 sccm, a flow rate of an inert gas (Ar or He) is set at 50 -150 sccm, and a flow rate of O₂, if required, is controlled at 5-20 sccm. The precise control of these parameters is critical to the etching rate and quality. Excessively low flow rates may lead to insufficient supply of reactants and limited etching rates, while excessively high flow rates may cause active particles to be discharged before fully reacting, consequently reducing the etching effect. Therefore, it is necessary to optimize the flow rate settings through experiments to determine the appropriate optimal range. Power settings are equally critical. The ICP source power is generally set within a range of 2000-5000 W, which can effectively increase plasma density and directly affect the etching rate. The radio frequency (RF) bias power is adjusted within a range of 1000-3000 W to enhance the kinetic energy of ion bombardment and achieve better anisotropy. Excessively high power may cause damage to the photoresist or film layer, which makes it necessary to ensure a balance between etching efficiency and material integrity when adjusting the power.

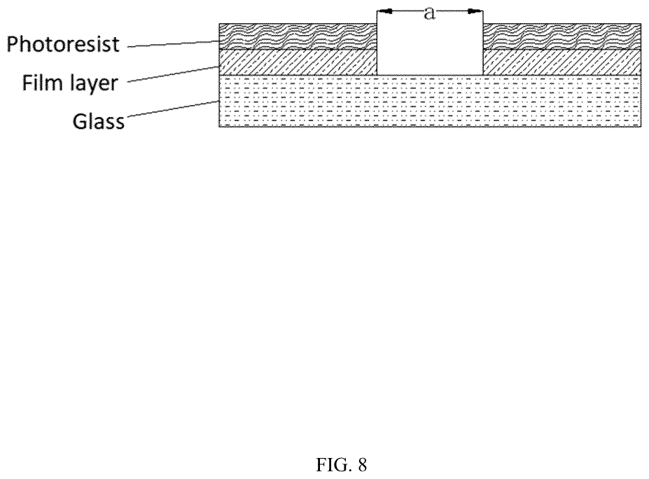

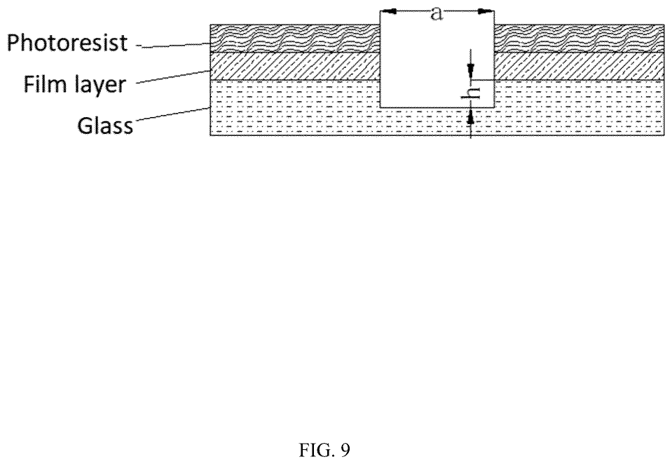

In the dry etching step according to the present disclosure, after the glass substrate has been subjected to the preliminary MASK pattern transfer and the film layer perforation treatment, the glass substrate only forms the aperture “a” on the surface at the film layer position as shown in FIG. 8, and the glass body has not been directly etched. By using plasma technology to perform directional longitudinal etching on the glass, a certain depth “h” can be dug out inside the glass while the aperture “a” remains substantially unchanged, as shown in FIG. 9. From “a” to “h”, the most essential change brought about by dry etching is presented, achieving the transformation from simple “aperture opening” to actual “recessed structure”, and the regions that originally only had film layer apertures are gradually evolved into vertical channels or concave areas with controllable depths in the glass body.

As can be seen from the comparison between FIG. 8 and FIG. 9, the microstructure obtained after dry etching is not simply an expansion in the direction of “a”; instead, a certain depth (h) is vertically etched into the glass while ensuring that the aperture width (a) remains substantially unchanged. The technical principle underlying such a practice lies in the synergistic effect of all components in the C₄F₆+H₂+Ar (or C₄F₆+CH₂F₂+Ar) plasma utilized in dry etching:
\textcircled{1} After being excited by high-energy plasma, C₄F₆ is ionized and decomposed into CF_{X} radicals, these CF_{X} radicals are the primary active species that chemically react with SiO₂ on the glass surface, and they either form chemical bonds with SiO₂ or disrupt the existing chemical bonds of SiO₂.
\textcircled{2} H₂ or CH₂F₂ acts as an “ion scavenger” that suppresses the consumption of F⁻ radicals, and generates HF volatiles in the etched area, which weakens the corrosion of non-target areas by F⁻radicals, thereby achieving “directional” etching.
\textcircled{4} Driven by the electric field, Ar ions bombard the etched area vertically, which not only strips off the reaction products, but also enhances the anisotropic etching effect on the sidewalls, allowing the etching path to penetrate deeper into the glass in the longitudinal direction.

The directional etching obtained by this synergistic effect keeps the aperture “a” basically at its original size and avoids excessive lateral expansion, but forms high-depth longitudinal cavities with dimensions ranging from sub-micrometers to several micrometers (with etching depths h reaching up to 0.1-10 μm, or even greater). The high-aspect-ratio structures formed by dry etching provide an ideal morphological foundation for subsequent wet etching. This etching strategy that prioritizes longitudinal depth not only significantly expands the effective light-scattering area, but also reserves ample space for the precision tuning of microstructures in later stages, thereby achieving enhanced anti-glare performance and effective suppression of sparkle points.

From the perspective of micromorphology, the structural characteristics after dry etching are mainly reflected in two aspects: the sidewalls and the bottom. The sidewalls exhibit relatively straight profiles with distinct anisotropic features. Driven by the synergistic effect of Ar ion bombardment and CFX radicals, micron-scale steps may be formed on the sidewalls. Meanwhile, nanoscale microscopic roughness appears on the bottom, which is mainly caused by the ion bombardment effect during plasma etching and the difference in local reaction rates. By adjusting parameters such as etching temperature (20-300 ° C), gas flow ratio, RF power and working pressure, the sidewall inclination angle and bottom morphology can be controlled to a certain extent.

### H. Wet Etching 1

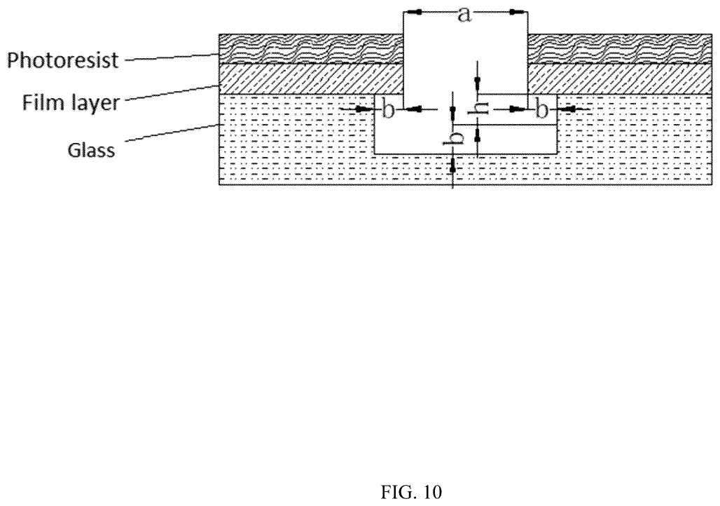

As shown in FIG. 10, after dry etching, the process according to the present disclosure proceeds to the wet etching stage. In this step, isotropic etching is performed on the microstructures using chemical reagents to achieve a transition from simple longitudinal recesses to complex three-dimensional structures. The parameter “b” in the figure denotes the etching width and depth achieved by wet etching in both transverse and longitudinal directions simultaneously. This synchronous expansion is a direct manifestation of the isotropic characteristic of wet etching.

In terms of the final etched morphology, the following significant changes can be observed by comparing the morphology after dry etching (FIG. 9) with the structure after wet etching (FIG. 10): \textcircled{1} the width of a microstructure opening is expanded from the initial “a” to “a+2b”, and thus the lateral dimension is significantly increased; \textcircled{2} the depth is further increased from the dry etching depth “h” to “h+b”, enhancing the overall aspect ratio; and \textcircled{3} the originally relatively straight sidewalls exhibit obvious smooth transitions after wet etching, and the overall profiles of the microstructures become smoother and more continuous. This morphological evolution lays a foundation for the subsequent optimization of optical performance (Note: For the convenience of illustration, straight lines are used instead of the actual profile in the figures, which does not affect the representation of the actual etched morphology).

A wet etching solution is manufactured with a single acid or mixed acid system, including but not limited to hydrofluoric acid (HF) or ammonium fluoride (NH₄F) used as a main etching agent, with inorganic or organic acids such as hydrochloric acid, nitric acid, sulfuric acid, and acetic acid being selectively added as auxiliary acidic components; and for instance, HF/NH₄HF₂ mainly provides the basic etching capability for silicate structures (predominantly SiO₂), while HCl/HNO₃/H₂SO₄/HAc is primarily used for adjustment of the etching rate and buffer reaction by-products and for fine tuning of surface roughness, which facilitates the achievement of a more uniform etched morphology. The process temperature is controlled within a range of 20-50 °C, and this temperature range ensures sufficient reaction activity while avoiding reaction runaway and bubble generation that might be caused by excessively high temperatures. According to the specific requirement, a trough-type or horizontal etching machine may be employed as wet etching equipment.

### I. Photoresist stripping

Photoresist stripping technology is employed to remove residual photoresist, yielding the final microstructure pattern. The photoresist removal method may be either wet stripping or dry stripping, with a processing duration of 1-15 min. This step ensures that no residual substances remain on the surface, so as to enable the manufacturing for subsequent treatments.

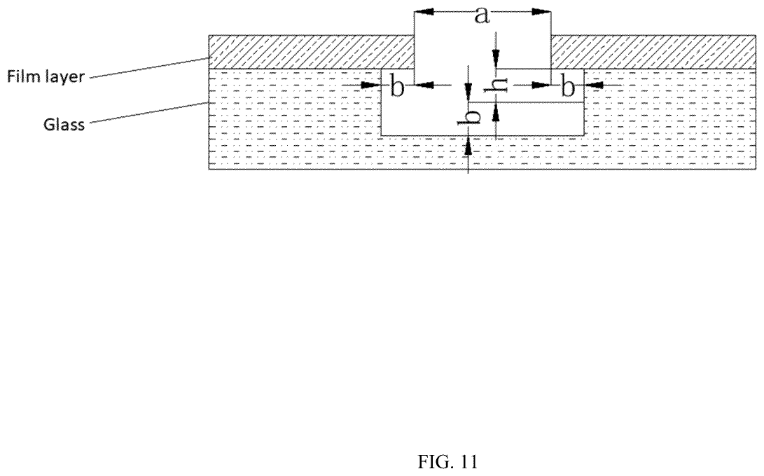

As shown in FIG. 11, after the completion of the dry etching and the first wet etching, the photoresist has been completely removed. It is specifically noted that the photoresist stripping step according to the present disclosure features high process flexibility; its sequence within the overall process flow can be adjusted according to actual requirements, and the example depicted in the figure represents only one possible scenario; and for instance, an alternative process sequence, i.e., photoresist stripping→wet etching of glass→film layer removal, may also be adopted. This flexibility enhances the adaptability of the manufacturing process. Regardless of the sequence adopted, all such variations fall within the protection scope of this patent.

### J. Film layer removal

Regarding film layer removal, a corresponding wet etching solution can be selected based on the properties of a film layer. For ITO, Cr and Mo film layers, a mixed solution of nitric acid or hydrochloric acid is mainly used, with a concentration controlled within a range of 1-10%; for SiO₂ film layers, hydrofluoric acid is adopted, with a concentration generally set at 5-20%; while for Si₃N₄ film layers, phosphoric acid is used, with a concentration range of 10-30%. According to the production scale, a trough-type or horizontal etching machine may be employed as etching equipment. The specific etching parameters (such as temperature and time) depend on the material and thickness of the film layer and the characteristics of the etching solution used. Under normal circumstances, the etching temperature is controlled within a range of 20-50 °C, and the etching time is adjusted according to actual conditions until the film layer is completely removed. To avoid damage to the glass surface caused by excessive etching, it is necessary to monitor the etching process in real time and terminate the reaction promptly.

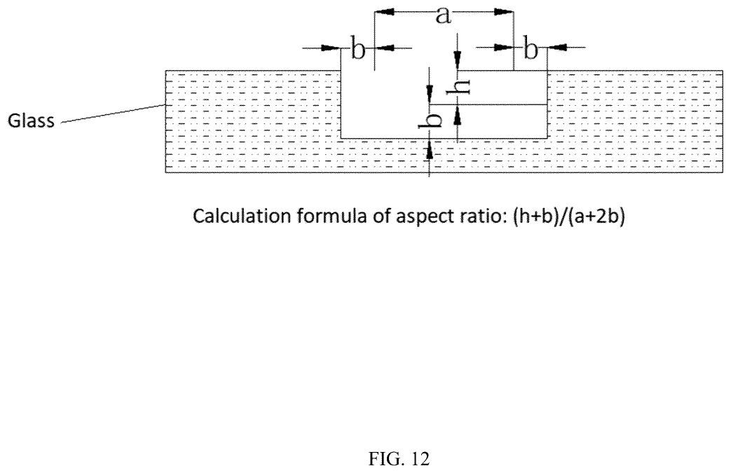

As shown in FIG. 12, after the completion of film layer removal, a specific microstructure morphology is formed on the surface of the glass substrate. The longitudinal depth “h” of the microstructure, together with the transverse widths “a” and “b”, constitutes the aspect ratio of the entire structure, with a calculation formula being: aspect ratio=(h+b)/(a+2b). This formula indicates that by increasing the longitudinal depth (h), the overall aspect ratio can be effectively improved, thereby enlarging the effective anti-glare area.

After undergoing this series of processes, the finally formed microstructures exhibit excellent anti-glare performance, achieving an effect comparable to that manufactured by the conventional frosting method while outperforming the frosting process in sparkle point control.

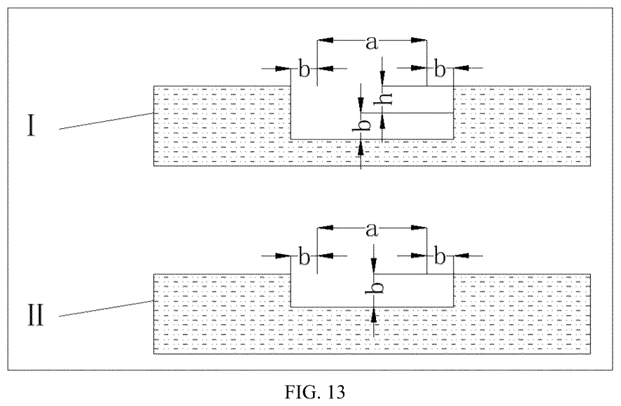

As shown in FIG. 13, diagram I: a schematic diagram of the structure of dry etching+wet etching (after photoresist stripping and film layer removal); diagram II: a schematic diagram of the structure of wet etching (after photoresist stripping and film layer removal).

As shown in the figures, there are significant differences in the microstructure morphologies obtained by the hybrid dry-wet etching process (diagram I) and the simple wet etching process (diagram II). For the hybrid dry-wet etching process, a relatively deep longitudinal etching depth is first formed via dry etching, followed by simultaneous lateral and vertical expansion using wet etching; and the planar visualized area of the finally obtained microstructure may be expressed as (a+2b)×(h+b), where “a+2b” represents the final aperture in the transverse direction, and “h+b” reflects the superposition of longitudinal depth and sidewall expansion. In contrast, the planar visualized area of the microstructure obtained by conventional simple wet etching is (a+2b)×b, which corresponds to a pit formed on the glass surface with a depth of b and a total transverse width of a+2b. Consequently, its effective light-scattering area is relatively reduced.

In terms of anti-glare performance, since the microstructures etched by the hybrid dry-wet etching process feature greater longitudinal depth, their surface areas increase approximately exponentially with the increase of etching depth. A larger surface area means that under strong light irradiation, incident light undergoes more times of scattering and attenuation inside the pits and on the sidewalls, thereby effectively reducing the intensity of direct light and mitigating glare. Such geometric expansion plays a vital role. The wide and sufficiently deep pit structures not only disperse light in multiple directions, but also disrupt the coherent paths of light to a certain extent, leading to the adequate attenuation of glare.

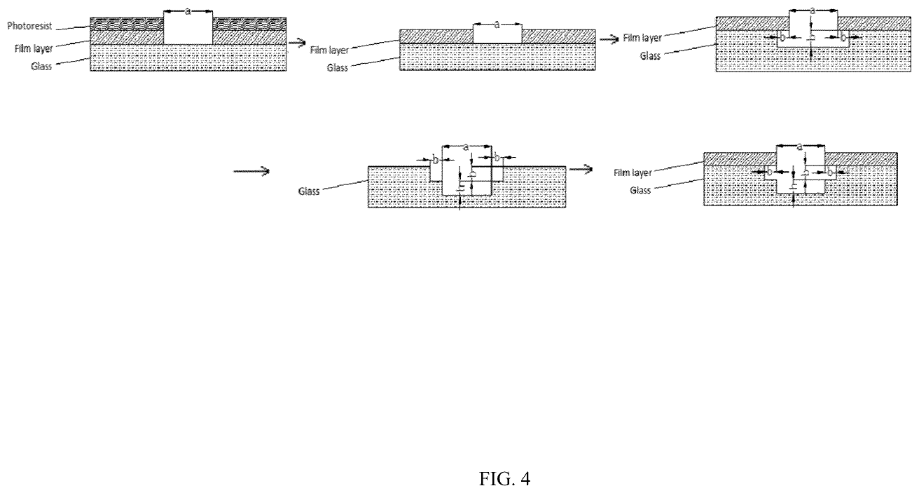

In addition to the process of dry etching followed by wet etching, FIG. 4 to FIG. 6 illustrate the process flow of wet etching 1 first followed by dry etching, which exhibits significant differences in microstructure morphology control and optical performance adjustment:

In terms of morphology, in the process of wet etching first and then dry etching, the initial wet etching leverages its isotropic characteristics to form primary pits with wide openings and smooth profiles on the glass surface. In this case, the microstructures already possess basic light-scattering functionality, but their aspect ratio is relatively limited. Subsequent dry etching, based on these pre-formed pits, further increases the depth of the central area through the action of highly directional plasma, thereby forming a “wide mouth and deep bottom” composite structure. This structure integrates both the large-area light-scattering characteristic of wet etching and the high-aspect-ratio characteristic of dry etching. In contrast, the conventional dry-first process first forms deep and narrow vertical channels via directional plasma etching, and subsequent wet etching expands the widths of these channels, ultimately yielding tapered or funnel-shaped structures with the feature of “narrow openings gradually widening outward”. These two distinct morphology evolution pathways lead to inherent differences in the light-scattering characteristics of the final microstructures.

From the perspective of optical performance, the microstructures fabricated by the process of wet etching first and then dry etching exhibit multi-level light-scattering characteristics. The shallow microstructures formed by the initial wet etching provide preliminary surface scattering capability, which is suitable for handling large-angle incident light, while the deep structures added by the subsequent dry etching enhance the scattering capability for small-angle incident light. This hierarchical scattering mechanism enables the final AG glass to maintain excellent anti-glare performance under different lighting conditions.

### K. Wet etching 2

The wet etching 2 stage is a critical step for achieving the final microstructure morphology and performance optimization. This process is intended to further refine the formed microstructures to meet the required final matte finish requirement.

Similar to wet etching 1, the etching solutions used in wet etching 2 include but are not limited to single or mixed acids such as HF and NH₄HF₂, with inorganic or organic acids such as hydrochloric acid, nitric acid, sulfuric acid, and acetic acid being selectively added as auxiliary acidic components. During the etching process, it is necessary to periodically inspect the solution concentration, temperature and etching rate, so as to adjust the process parameters based on real-time data. By maintaining proper agitation of the solution, accumulation of reaction products can be avoided, which further improves the etching uniformity and efficiency.

The present disclosure proposes an innovative hybrid dry-wet etching process in the technical field of AG glass manufacturing, and its core technical features and protection points are mainly reflected in the following aspects:

First, the fundamental innovation of the present disclosure lies in the manufacturing method integrating dry etching and wet etching. This composite process breaks through the limitations of conventional single etching processes and innovatively proposes a novel approach for the manufacturing of AG glass. Therefore, all methods adopting dry etching technology during the AG glass manufacturing process, regardless of their specific process parameters or equipment selections, fall within the protection scope of this patent.

Second, the present disclosure innovatively breaks through the fixed order restrictions of dry etching and wet etching in conventional processes, and explicitly incorporates processes in which dry etching may be performed either before or after wet etching into the protection scope. This flexible process layout provides broader technical approaches for the precision tuning of microstructure morphology, enabling the selection of an optimal etching sequence according to the performance requirements of different application scenarios. Whether the conventional process route of “dry etching first followed by wet etching” or the innovative process route of “wet etching first followed by dry etching” is adopted, all such processes fall within the protection scope of this patent as long as they embody the core concept of combining dry etching with wet etching.

Third, the present disclosure particularly emphasizes a precise control solution for the aspect ratio of microstructures. Specifically, it is manifested as follows: first, an initial structure with a longitudinal depth of 0.1-10 μm is formed by dry etching, followed by bidirectional three-dimensional etching in both longitudinal and transverse directions (5-100 μm) using wet etching. This technical solution that enhances the anti-glare effect by increasing the aspect ratio constitutes important content claimed for protection in the present disclosure. All manufacturing methods adopting similar parameter ranges and process concepts fall within the protection scope of this patent.

Fourth, the present disclosure expands the selection range of film layer materials. In the hybrid dry-wet etching process, all technical solutions that employ materials such as ITO, Cr, Mo, SiO₂ and Si₃N₄ as film layers and combine with the dry etching process fall within the protection scope of the present disclosure. Whether a single type of the aforementioned materials is used alone, or multiple materials are combined to construct the film layer structure, all such solutions for manufacturing AG glass by combining the film layer with the dry etching process are included in the core protection scope of the present disclosure.

The above four key technical features are interrelated and indispensable, jointly forming the complete technical solution of the present disclosure. These features not only embody the innovation of the present disclosure but also lay a foundation for subsequent technological development. Through the comprehensive protection of these key points, the technical advantages and patent value of the present disclosure in the field of AG glass manufacturing are ensured.

The foregoing descriptions are merely exemplary embodiments of the present disclosure. The scope of the present disclosure is defined by the appended claims and encompasses all modifications and equivalent arrangements based on the technical features described above.

The present disclosure has been exemplarily described above in conjunction with the accompanying drawings. Obviously, the specific implementation of the present disclosure is not limited by the foregoing embodiments. Various non-substantive improvements made by adopting the concept and technical solution of the present disclosure, or direct applications of the concept and technical solution of the present disclosure to other occasions without improvement, shall fall within the protection scope of the present disclosure.

What is claimed is:

1. A method for manufacturing anti-glare glass, comprising the following steps:
step 1: performing surface cleaning on a glass substrate;
step 2: depositing a film layer on a surface of the glass substrate;
step 3: coating the film layer with photoresist;
step 4: carrying out exposure, development and film layer etching; and
step 5: performing dry etching to directionally etch a longitudinal depth of the glass, followed by wet etching to simultaneously etch in both longitudinal and transverse directions to obtain a specific aspect ratio and increase an anti-glare area; or performing wet etching to construct a preliminary morphology on the glass surface, followed by dry etching to achieve precise depth control and feature shaping in specific areas,
wherein
a process flow in step 5 is as follows: dry etching of glass→photoresist stripping→wet etching of glass 1→film layer removal→wet etching of glass 2;
or dry etching of glass→wet etching of glass 1→photoresist stripping→film layer removal→wet etching of glass 2; or photoresist stripping→dry etching of glass→wet etching of glass 1→film layer removal→wet etching of glass 2; or photoresist stripping→wet etching of glass 1→dry etching of glass→film layer removal→wet etching of glass 2; or wet etching of glass 1→photoresist stripping→dry etching of glass→film layer removal→wet etching of glass 2; or wet etching of glass 1→dry etching of glass→photoresist stripping→film layer removal→wet etching of glass 2;
in step 2, a thickness of the film layer ranges from 50 Å to 3000 Å, and the film layer is formed by vacuum deposition or evaporation deposition;
in step 3, a thickness of the photoresist ranges from 0.5 μm to 20 μm; the coating is performed by a slot die coating method, with a coating speed controlled within a range of 10-200 mm/s, and a spray pressure maintained at 0.03-0.98 MPa; and after the coating, a soft bake is carried out at 50-200°C for 30-300 s;
in step 4, for the exposure process, a contact aligner, a proximity aligner, or a projection aligner is selected according to batch and resolution requirements, with exposure energy ranging from 50 mJ/cm² to 500 mJ/cm²;
in step 4, the development lasts for 30-90 s and is maintained at a constant temperature within a range of 20-30°C, and a conductivity of a developing solution is kept within a range of 1-80 mS/cm;
after the development, a post-development bake is carried out at 50-300°C for 1-20 min; prior to the film layer etching, a photoresist pattern is cured by thermal curing or ultraviolet (UV) curing at 50-500°C for 1-60 min to enhance the etch resistance and mechanical strength of the photoresist pattern and prevent deformation or delamination during the etching process; and
in step 5, during the wet etching stage, isotropic etching is performed on the microstructures using chemical reagents to achieve a transition from simple longitudinal recesses to complex three-dimensional structures; and the wet etching is performed to simultaneously etch the width and depth in both the transverse and longitudinal directions, so as to increase the aspect ratio and enhance the anti-glare effect.

2. The method for manufacturing anti-glare glass according to claim 1, wherein in step 1, preliminary rinsing is performed on the surface of the glass substrate with deionized water in combination with a soft brush or ultrasonic means to remove dust and organic impurities therefrom;
or a cleaning agent or solvent is added for degreasing and oil removal at 20-100 °C for 1-10 min.

3. The method for manufacturing anti-glare glass according to claim 1, wherein in step 5, the dry etching process is as follows:
in the dry etching step, an inductively coupled plasma technology is used for precise microstructure processing of anti-glare glass; and the dry etching is used for performing directional etching on the glass by a plasma etching technology;
in terms of process parameter setting, a vacuum system is maintained at 0.1-10 Torr to ensure the stability of plasma and sufficient dissociation of gases; and in terms of gas flow rates, flow rates of main etching gases are controlled within a range of 50-200 sccm, a flow rate of an inert gas is set at 50 -150 sccm, and a flow rate of O₂, if required, is controlled at 5-20 sccm.
